(19) United States
(12) Patent Application Publication
(10) Pub. No.: US 2026/0304747 A1
(43) Pub. Date: Oct. 1, 2026

(54) SEMICONDUCTOR DEVICE AND MANUFACTURING METHOD THEREFOR, AND ELECTRONIC DEVICE

(71) Applicant: BEIJING SUPERSTRING ACADEMY OF MEMORY TECHNOLOGY, Beijing (CN)

(72) Inventors: Yuke Li, Beijing (CN); Shujuan Mao, Beijing (CN); Honggang Liang, Beijing (CN)

(73) Assignee: BEIJING SUPERSTRING ACADEMY OF MEMORY TECHNOLOGY, Beijing (CN)

(21) Appl. No.: 19/475,402

(22) PCT Filed: Oct. 10, 2023
(86) PCT No.: PCT/CN2023/123825

§ 371 Date: Oct. 14, 2025

(30) Foreign Application Priority Data
Apr. 24, 2023 (CN) 202310450191.0

(51) Int. Cl. H10B 12/00

(52) U.S. Cl. CPC H10B 12/315; H10B 12/05; H10B 12/50

(57) ABSTRACT

A semiconductor device and a manufacturing method therefor, and an electronic device. The semiconductor device comprises: a first wafer (100) and a second wafer (200) arranged on the first wafer (100), the first wafer (100) comprising a substrate (1) and a bit line arranged on the substrate (1), and the second wafer (200) comprising at least one transistor, wherein the transistor comprises a semiconductor pillar (10) extending in a direction perpendicular to the substrate (1); the semiconductor pillar (10) comprises a channel region (11), and a first region (12) and a second region (13) which are respectively arranged on two sides of the channel region (11); the second region (13) is arranged on the side of the channel region (11) that faces the substrate (1); and the bit line (30) is in contact with the second region (13).

### CROSS-REFERENCE TO RELATED APPLICATIONS

The present application is a U.S. National Phase Entry of International PCT Application No. PCT/CN2023/123825 having an international filing date of Oct. 10, 2023, which claims priority to Chinese Patent Application No. 202310450191.0 filed to the China National Intellectual Property Administration on Apr. 24, 2023 and entitled “Semiconductor Device, Manufacturing Method therefor, and Electronic Device”. The above-identified applications are incorporated by reference herein in their entireties.

### TECHNICAL FIELD

Embodiments of the present disclosure relate to, but are not limited to, semiconductor technologies, in particular to a semiconductor device, a method for manufacturing the semiconductor device, and an electronic equipment.

### BACKGROUND

With the development of integrated circuit technology, the key dimensions of devices are shrinking day by day, and the types and quantities of devices contained in a single chip are increasing, so that any slight differences in process production may affect the performance of devices.

In order to reduce the cost of products as much as possible, people want to make as many device cells as possible on a limited substrate. Since Moore's Law came out, the industry has proposed various semiconductor structure designs and process optimizations to meet people's demands for current products.

### SUMMARY

The following is a summary of the subject matter described in detail in this document. This summary is not intended to limit the scope of protection of the claims.

Embodiments of the present disclosure provide a semiconductor device including a first wafer and a second wafer disposed on the first wafer, wherein the first wafer includes a substrate and a bit line disposed on the substrate; the second wafer includes at least one transistor including a semiconductor pillar extending in a direction perpendicular to the substrate, the semiconductor pillar includes a channel region and a first region and a second region respectively disposed on two sides of the channel region, the second region is disposed on a side of the channel region facing the substrate, and the bit line is in contact with the second region.

In some embodiments, the contact surface of the bit line with the second region is parallel to the substrate.

In some embodiments, the surface of the bit line close the substrate is parallel to the substrate.

In some embodiments, an orthographic projection of the bit line includes a rectangle on a plane parallel to the substrate.

In some embodiments, the second wafer includes a plurality of transistors distributed in an array along a first direction and a second direction respectively, the first wafer includes a plurality of bit lines extending along the second direction, second regions of transistors of a same column distributed along the second direction are connected to a same bit line, and the first direction and the second direction intersect.

In some embodiments, the transistor further includes a gate electrode surrounding a sidewall of the channel region, and gate electrodes of a same row of transistors distributed along the first direction are connected to form a word line.

In some embodiments, the semiconductor device further includes a logic circuit disposed on a side of the bit line away from the second wafer.

In some embodiments, an orthographic projection of the logic circuit on the substrate overlaps with an orthographic projection of the transistor on the substrate.

An embodiment of the present disclosure provides an electronic equipment including the semiconductor device described in any of the above embodiments.

In some embodiments, the semiconductor device further includes a capacitor disposed on a side of the transistor away from the first wafer, the capacitor includes a first capacitive electrode, a second capacitive electrode, and a dielectric layer disposed between the first capacitive electrode and the second capacitive electrode, the first capacitive electrode is connected to the first region through a node contact layer.

An embodiment of the present disclosure provides a method for manufacturing a semiconductor device, wherein the semiconductor device includes at least one transistor including a semiconductor pillar, and the method includes:
providing a first wafer including a substrate, and forming a bit line layer on the substrate;
providing a second wafer including a base substrate and a semiconductor layer disposed on the base substrate, inverting the second wafer, bonding a side of the second wafer away from the base substrate to the first wafer, removing the base substrate by etching to expose the semiconductor layer, wherein the bit line layer is in contact with the semiconductor layer; and
etching the semiconductor layer and the bit line layer to form at least one semiconductor pillar extending in a direction perpendicular to the substrate, the semiconductor pillar including a channel region and a first region and a second region respectively disposed on two sides of the channel region, with the second region being disposed on a side of the channel region facing the substrate, and forming at least one bit line, with the second region being in contact with the bit line.

In some embodiments, the etching the semiconductor layer and the bit line layer includes:
forming a plurality of word line isolation trenches extending in a first direction, the word line isolation trenches penetrating the semiconductor layer and exposing the bit line layer, and the word line isolation trenches dividing the semiconductor layer into a plurality of semiconductor portions;
forming a plurality of bit line isolation trenches extending in a second direction and penetrating the bit line layer, the bit line isolation trenches dividing the bit line layer into a plurality of bit lines, the second direction intersecting the first direction.

In some embodiments, the providing the second wafer includes epitaxially growing on the base substrate and doping the base substrate to form a semiconductor layer.

In some embodiments, the forming the bit line layer on the substrate includes:
depositing a first insulating thin film on the substrate to form a first insulating layer;
sequentially depositing a first conductive thin film and a connection layer thin film on the first insulating layer to form the bit line layer by patterning;

Or, depositing a first insulating thin film on the substrate to form a first insulating layer;
depositing a first conductive thin film after etching a trench on the first insulating layer, and planarizing the first conductive thin film to form a first conductive layer disposed in the trench;
depositing a connection layer thin film and patterning the connection layer thin film to form a connection layer, wherein the first conductive layer and the connection layer constitute the bit line layer, and an orthographic projection of the connection layer on the substrate overlaps with an orthographic projection of the first conductive layer on the substrate.

In some embodiments, before forming the bit line layer on the substrate, the method further includes forming a logic circuit on the substrate.

Other features and advantages of the present disclosure will be set forth in the following specification, and moreover, partially become apparent from the specification, or are understood by implementing the present disclosure. The objectives and advantages of the present disclosure can be achieved through structures particularly pointed out in the specification and the drawings.

Other aspects may be understood upon reading and understanding the drawings and detailed description.

### BRIEF DESCRIPTION OF DRAWINGS

Accompanying drawings are used to provide further understanding of technical solutions of the present disclosure, constitute a part of the specification, and are used to explain the technical solutions together with the embodiments of the present disclosure but not to form limitations on the technical solutions of the present disclosure.

FIG. 1A is a schematic plan view of a semiconductor device according to an exemplary embodiment.

FIG. 1B is a cross-sectional view along the direction AA′ in FIG. 1A.

FIG. 2A is a top view after a bit line layer is formed according to an exemplary embodiment.

FIG. 2B is a cross-sectional view along the AA′ direction after a bit line layer is formed according to an exemplary embodiment.

FIG. 2C is a cross-sectional view along the AA′ direction after a bit line layer is formed according to another exemplary embodiment.

FIG. 3 is a cross-sectional view of a second wafer in a direction perpendicular to a base substrate according to an exemplary embodiment.

FIG. 4 is a cross-sectional view along a direction perpendicular to a substrate after bonding according to an exemplary embodiment;

FIG. 5 is a cross-sectional view along the AA′ direction after a word line isolation trench is formed according to an exemplary embodiment.

FIG. 6 is a cross-sectional view along the AA′ direction after a third insulating layer and a fourth insulating layer are formed according to an exemplary embodiment.

FIG. 7A is a cross-sectional view along the AA′ direction after a bit line is formed according to an exemplary embodiment.

FIG. 7B is a cross-sectional view along the CC′ direction after a bit line is formed according to an exemplary embodiment.

FIG. 8 is a cross-sectional view along the AA′ direction after a channel region and a first region are exposed according to an exemplary embodiment.

FIG. 9 is a cross-sectional view along the AA′ direction after a gate insulating layer and a gate electrode are formed according to an exemplary embodiment.

FIG. 10 is a cross-sectional view along the AA′ direction after of a node contact layer is formed according to an exemplary embodiment.

FIG. 11 is a cross-sectional view along the AA′ direction after a capacitor is formed according to an exemplary embodiment.

FIG. 12 is a cross-sectional view along the AA′ direction after interconnection is implemented according to an exemplary embodiment.

FIG. 13 is a flowchart of a method for manufacturing a semiconductor device according to an exemplary embodiment.

### DESCRIPTION OF REFERENCE NUMBERS

1—substrate; 2—first insulating layer; 3—second insulating layer; 4—third insulating layer; 5—fourth insulating layer; 6—fifth insulating layer; 7—sixth insulating layer; 8—seventh insulating layer; 9 semiconductor layer; 9′—semiconductor portion; 10—semiconductor pillar; 11—channel region; 12—first region; 13—second region; 14—gate insulating layer; 20—word line; 21—gate electrode; 30 bit line; 30′—bit line layer; 31—first conductive layer; 32—connection layer; 40—node contact layer; 41—first capacitive electrode; 42—second capacitive electrode; 43—dielectric layer; 81—first connection electrode; 82—second connection electrode; 100—first wafer; 110—logic circuit; 200 second wafer; 210—base substrate.

### DETAILED DESCRIPTION

The embodiments of the present disclosure will be described in detail below in with reference to the accompanying drawings. The embodiments in the present application and features in the embodiments may be combined with each other randomly if there is no conflict.

Unless otherwise defined, technical terms or scientific terms used in the present disclosure shall have general meanings as understood by those of ordinary skills in the art to which the present disclosure pertains.

An implementation of the present disclosure is not necessarily limited to dimensions shown in the drawings, and the shapes and sizes of the components in the drawings do not reflect actual scales. Further, the drawings schematically illustrate ideal examples, but embodiments of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain positional relationship of the constituent elements with reference to the accompanying drawings, they are employed for ease of description of the specification and simplification of the description only, but do not indicate or imply that the referred apparatus or element must have a particular orientation and be constructed and operate in a particular orientation, and therefore cannot be construed as limitations on the present disclosure. The positional relationship of the constituent elements is appropriately changed according to a direction in which various constituent elements are described. Therefore, the present disclose is not limited to the words or expressions described in the present disclosure, and replacement may be appropriately made according to the situation.

In the present disclosure, terms “mount”, “couple” and “connect” should be understood broadly, unless otherwise expressly specified and defined. For example, it may be a fixed connection, a detachable connection, or an integral connection; it may be a mechanical connection or an electrical connection; it may be a direct connection, an indirect connection through a middleware, or an internal communication between two elements. For those of ordinary skills in the art, specific meanings of the above terms in the present disclosure may be understood according to actual situations.

In the present disclosure, a transistor refers to an element including at least three terminals, i.e., a gate electrode, a drain electrode, and a source electrode. A transistor has a channel region between a drain electrode (drain electrode terminal, drain region, or drain) and a source electrode (source electrode terminal, source region, or source), and a current can flow through the drain electrode, the channel region, and the source electrode. In the present disclosure, the channel region refers to the region through which the current mainly flows.

In the present disclosure, a “connection” includes a case where constituent elements are connected together through an element having a certain electrical effect. There is no special restriction on “elements with certain electrical effects” as long as they can transmit and receive electrical signals between connected constituent elements. Examples of “elements having certain electrical effects” include not only electrodes and wirings, but also switching elements (such as transistors), resistors, inductors, capacitors, and other elements having various functions, etc.

In the present disclosure, “parallel” refers to approximately parallel or almost parallel, for example, a state in which the angle formed by two straight lines is −10 degrees or more and 10 degrees or less, and therefore further includes a state in which the angle is −5 degrees or more and 5 degrees or less. In addition, “perpendicular” refers to “approximately perpendicular”, for example, a state in which the angle formed by two straight lines is 80 degrees or more and 100 degrees or less, and therefore further includes a state in which the angle is 85 degrees or more and 95 degrees or less.

“An orthographic projection of B is within a range of an orthographic projection of A” in the present disclosure means that a boundary of the orthographic projection of B falls within a range of a boundary of the orthographic projection of A, or the boundary of the orthographic projection of A coincides with the boundary of the orthographic projection of B.

“A and B are of an integrated structure” in embodiments of the present disclosure may mean that there is no obvious boundary interface, such as obvious faultage or gaps, viewed from the microstructure. Generally, connected film layers formed by patterning on one film layer are an integrated structure. For example, A and B form one film layer using a same material and simultaneously form a structure with a connection relationship through the same patterning process.

In a technical solution, the bit line is formed by etching a trench at bottom of a semiconductor pillar and filling a conductive material therein, which is difficult in processing, and uniformity of the formed bit line is not good, and holes are easily formed inside the bit line, resulting in different resistances and high resistances of different bit lines. In addition, it is difficult to form reliable ohmic contact between the bit line and a drain terminal, resulting in high contact resistance.

In the embodiment of the present disclosure, two wafers are used, a transistor is manufactured on one wafer, a bit line layer is manufactured on the other wafer, and then the bit line layer is directly etched to form a bit line, the bit line is manufactured without need of etching a trench at the bottom of the semiconductor pillar, so that the process can be simplified.

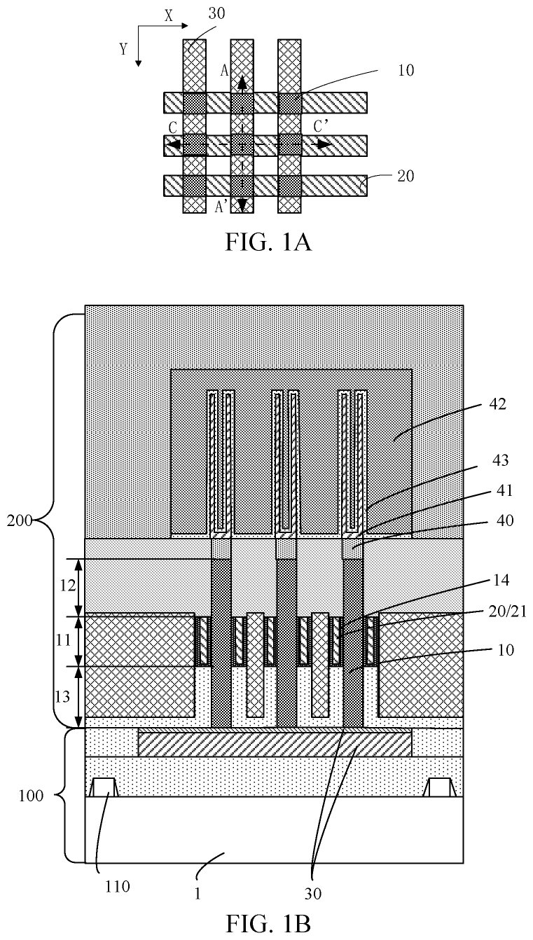

FIG. 1A is a schematic plan view of a semiconductor device according to an embodiment of the present disclosure, and FIG. 1B is a schematic cross-sectional view along an AA′ direction in FIG. 1A. As shown in FIGS. 1A and 1B, an embodiment of the present disclosure provides a semiconductor device that may include a first wafer 100 and a second wafer 200 disposed on the first wafer 100. The first wafer 100 may include a substrate 1 and a bit line 30 disposed on the substrate 1. The second wafer 200 may include at least one transistor including a semiconductor pillar 10 extending in a direction perpendicular to the substrate 1. The semiconductor pillar 10 includes a channel region 11 and a first region 12 and a second region 13 respectively disposed on two sides of the channel region 11. The second region 13 is provided on a side of the channel region 11 facing the substrate 1, and the bit line 30 is in contact with the second region 13.

The channel region 11 may be substantially distinguished from the first region 12 and the second region 13 by a position of a gate electrode, or may be substantially distinguished by differences in degrees of conductivity between the first region 12 and the second region 13 and the channel region 11. The second region 13, the channel region 11, and the first region 12 are sequentially distributed along an extension direction of the semiconductor pillar 10, that is, the semiconductor pillar 10 is divided into three parts along the extension direction of the semiconductor pillar 10, which are respectively the second region 13, the channel region 11, and the first region 12.

The first region 12 and the second region 13 may be regions in which the semiconductor pillar 10 is doped with impurities, and in one embodiment, a conductivity type of the first region 12 or the second region 13 may be n-type or p-type. The first region 12 may be a source region and the second region 13 may be a drain region, or the first region 12 may be a drain region and the second region 13 may be a source region. The channel region 11 may be doped, and doping concentrations of the first region 12 and the second region 13 may be greater than a doping concentration of the channel region 11, and doping concentrations of sidewalls of the first region 12 and the second region 13 may be greater than the doping concentration of the channel region 11.

In the scheme provided by this embodiment, two wafers are used, a transistor is provided on one wafer, and a bit line is provided on the other wafer. Compared with the scheme in the related art, in which a semiconductor pillar is provided on one wafer, and a bit line is formed by etching a trench at the bottom of the semiconductor pillar and filling a conductive material therein, the scheme of the embodiment of the present disclosure has simple process, can avoid the formation of a cavity in the bit line, and a shape of the bit line is easier to control and is more stable, and a contact resistance between the bit line and the semiconductor pillar is more stable. In addition, sizes and shapes of different bit lines of a same storage array are easier to control, and the sizes and shapes of different bit lines can be made uniform, so that a resistance of the bit line can be stabilized.

In an exemplary embodiment, the semiconductor pillar 10 extending in the direction perpendicular to the substrate 1 can be understood as substantially extending only in the direction perpendicular to the substrate 1, and the topography of the sidewalls of the semiconductor pillar 10 is smooth and defect-free.

In an exemplary embodiment, the transistor may further include a gate electrode 21, and the gate electrode 21 may surround a sidewall of the channel region 11. The semiconductor pillar 10 may include a bottom surface (a surface close to the substrate 1), a top surface (a surface away from the substrate 1), and a side surface located between the top surface and the bottom surface (i.e., a sidewall of the semiconductor pillar 10), and a sidewall of the channel region 11 is a part of the sidewall of the semiconductor pillar 10.

In an exemplary embodiment, the transistor may further include a gate insulating layer 14 surrounding the sidewall of the semiconductor pillar 10. The gate insulating layer 14 is located between the gate electrode 21 and the semiconductor pillar 10 to insulate the gate electrode 21 from the semiconductor pillar 10.

In an exemplary embodiment, the contact surface of the bit line 30 and the second region 13 may be parallel to the substrate 1. In this embodiment, since the bit line 30 is independently formed on the first wafer 100, it is not necessary to be formed by etching a trench at the bottom of the semiconductor pillar 10, an upper surface of the bit line 30 (a surface away from the substrate 1) may be parallel to the substrate 1.

In an exemplary embodiment, a surface of the bit line 30 close to the substrate 1 is parallel to the substrate 1. In this embodiment, both upper and lower surfaces of the bit line 30 are parallel to the substrate 1, and a resistance of the bit line is stable.

In an exemplary embodiment, sizes and shapes of cross sections of the bit line 30 in a direction parallel to the substrate 1 may be substantially the same at different positions. The bit line 30 of this embodiment has a stable shape of cross section and a more stable resistance as compared to a method in which a bit line is formed by etching a trench at the bottom of the semiconductor pillar 10 in the related art.

In an exemplary embodiment, sizes and shapes of cross sections of the channel region 11 in the direction parallel to the substrate 1 may be substantially the same at different positions.

In an exemplary embodiment, sizes and shapes of cross sections of the first region 12 in the direction parallel to the substrate 1 may be substantially the same at different positions.

In an exemplary embodiment, sizes and shapes of cross sections of the second region 13 in the direction parallel to the substrate 1 may be substantially the same at different positions.

In an exemplary embodiment, orthographic projections of the channel region 11, the first region 12, and the second region 13 on the substrate 1 may overlap. However, embodiments of the present disclosure are not limited thereto, and an orthographic projection of the channel region 11 on the substrate 1 may be within an orthographic projection of the first region 12 on the substrate 1, or the orthographic projection of the channel region 11 on the substrate 1 may be within an orthographic projection of the second region 13 on the substrate 1.

In an exemplary embodiment, the channel region 11, the first region 12, and the second region 13 may be connected to form an integrated structure, that is, the channel region 11, the first region 12, and the second region 13 are formed by patterning a same film layer. However, the embodiments of the present disclosure are not limit thereto.

In an exemplary embodiment, an orthographic projection of the bit line 30 includes a rectangle on a plane parallel to the substrate 1. However, the embodiments of the present disclosure are not limited thereto, and the orthographic projection of the bit line 30 may have other shapes.

In an exemplary embodiment, as shown in FIG. 1A, the semiconductor device may include a storage array including a plurality of transistors distributed in an array, that is, the second wafer 200 may include a plurality of transistors distributed in an array along a first direction X and a second direction Y respectively, and the first wafer 100 may include a plurality of bit lines 30 extending along the second direction Y. Second regions 13 of a same column of transistors distributed along the second direction Y are connected to a same bit line 30, and the first direction X and the second direction Y may intersect.

In an exemplary embodiment, the first direction X and the second direction Y may be perpendicular to each other.

In an exemplary embodiment, the first direction X may be parallel to the substrate 1, and the second direction Y may be parallel to the substrate 1.

In an exemplary embodiment, as shown in FIG. 1A, gate electrodes 21 of transistors in a same row distributed along the first direction X are connected to form a word line 20. The semiconductor device may include a plurality of word lines 20 distributed at intervals along the second direction Y.

In an exemplary embodiment, the semiconductor device may further include a logic circuit 110 disposed on the first wafer 100 on a side of the bit line 30 away from the second wafer 200.

In an exemplary embodiment, an orthographic projection of the logic circuit 110 on the substrate 1 and an orthographic projection of a transistor on the substrate 1 may overlap. In the scheme provided by this embodiment, the logic circuit is manufactured on another wafer where the transistor is not located. Compared with the scheme in which the logic circuit and the transistor are laid on the same wafer, the orthographic projections of the logic circuit and the transistor on the substrate overlaps, that is, the logic circuit and the transistor are stacked, so that an area occupied by the semiconductor device can be reduced, more semiconductor devices can be manufactured on a same plane, and a density of the semiconductor devices can be improved.

In an exemplary embodiment, the semiconductor device may further include an isolation structure filled between transistors, and a material of the isolation structure may include at least one of silicon oxide, silicon nitride, and silicon oxynitride.

In an exemplary embodiment, the semiconductor device may further include a data storage element.

In an exemplary embodiment, the data storage element is, for example, a capacitor, that is, a storage structure of 1T1C is formed. However, embodiments of the present disclosure are not limited thereto, and a storage structure of 2T0C, 2T1C, and the like can be formed with other transistors.

In an exemplary embodiment, as shown in FIG. 1B, the capacitor may include a first capacitive electrode 41 and a second capacitive electrode 42, and a dielectric layer 43 disposed between the first capacitive electrode 41 and the second capacitive electrode 42. The first capacitive electrode 41 is connected to the first region 12.

In an exemplary embodiment, the first capacitive electrode 41 may be connected to the first region 12 through a node contact layer 40.

Structures of the semiconductor device shown in FIGS. 1A and 1B are merely examples, and the embodiments of the present disclosure are not limited thereto, and may be other structures.

Technical solutions of the embodiments will be further explained through a manufacturing process of the semiconductor device of the embodiment. A “patterning process” mentioned in the embodiments includes film layer deposition, photoresist coating, mask exposure, development, etching, photoresist stripping, and other treatments, and is a mature manufacturing process in related technologies. A “photolithography process” in the embodiments includes film layer coating, mask exposure, and development, and is a mature manufacturing process in the related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a substrate using a deposition or coating process. If the “thin film” does not need a patterning process or photolithography process during the whole manufacturing process, the “thin film” may also be called a “layer”. If the “thin film” needs a patterning process or photolithography process during the whole manufacturing process, it is called a “thin film” before the patterning process and a “layer” after the patterning process. The “layer” after the patterning process or photolithography process contains at least one “pattern”.

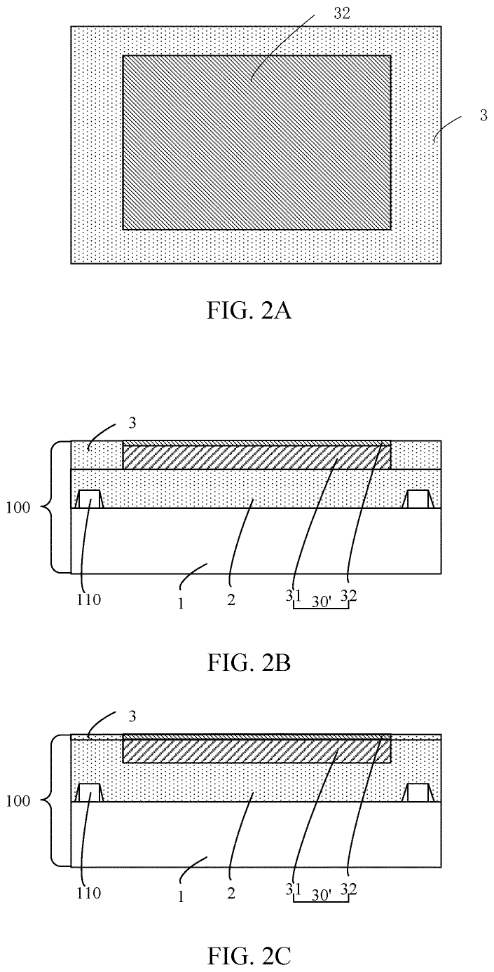

In an exemplary embodiment, the manufacturing process of the semiconductor device may include the following acts 1) to 11).
1) Forming a bit line layer 30′;
the forming the bit line layer 30′ may include:
providing a first wafer 100, wherein the first wafer 100 includes a substrate 1, and a logic circuit 110 is formed on the first wafer 100;
depositing a first insulating thin film on the substrate 1 on which the above structure is formed to form a first insulating layer 2, wherein the first insulating layer 2 covers the logic circuit 110;
depositing a first conductive thin film and a connection layer thin film sequentially on the first insulating layer 2, and patterning the first conductive thin film and the connection layer thin film to form a first conductive layer 31 and a connection layer 32, wherein the first conductive layer 31 and the connection layer 32 constitute a bit line layer 30′, and the bit line layer 30′ may form a plurality of bit lines 30 subsequently;
depositing a second insulating thin film on the substrate 1 on which the aforementioned structures are formed to form a second insulating layer 3, as shown in FIGS. 2A and 2B, wherein FIG. 2A is a top view after the bit line layer 30′ is formed, and FIG. 2B is a cross-sectional view along the AA′ direction after the bit line layer 30′ is formed. The AA′ direction is perpendicular to the substrate 1. The logic circuit 110 shown in FIG. 2B is only a part of the logic circuit, and the logic circuit 110 may be distributed at other positions. The orthographic projection of the logic circuit 110 on the substrate 1 may overlap with an orthographic projection of the bit line layer 30′ on the substrate 1, so that the area of the semiconductor device can be reduced and the density of semiconductor devices can be increased.

In an exemplary embodiment, the orthographic projections of the first conductive layer 31 and the connection layer 32 may overlap on a plane parallel to the substrate 1.

In an exemplary embodiment, on a plane parallel to the substrate 1, the orthographic projections of the first conductive layer 31 and the connection layer 32 may be rectangular, for example, be square, but not limited thereto, and they may be in other shapes. The first conductive layer 31 and the connection layer 32 may be adapted to a shape of a subsequent storage array, and an orthographic projection of the semiconductor pillar 10 on the substrate 1 falls within the orthographic projections of the first conductive layer 31 and the connection layer 32 on the substrate 1.

In an exemplary embodiment, the first conductive thin film includes, but is not limited to, tungsten (W), aluminum (Al), molybdenum (Mo), ruthenium (Ru), titanium (Ti), titanium nitride (TiN), tantalum (Ta), and the like.

In an exemplary embodiment, the connection layer thin film may be made of titanium (Ti), cobalt (Co), nickel platinum (NiPt), or the like.

In an exemplary embodiment, the first insulating film and the second insulating film may be one or more of silicon nitride (SiNx), silicon oxide (SiOx), silicon oxynitride (SiON), and silicon carbide (SiC).

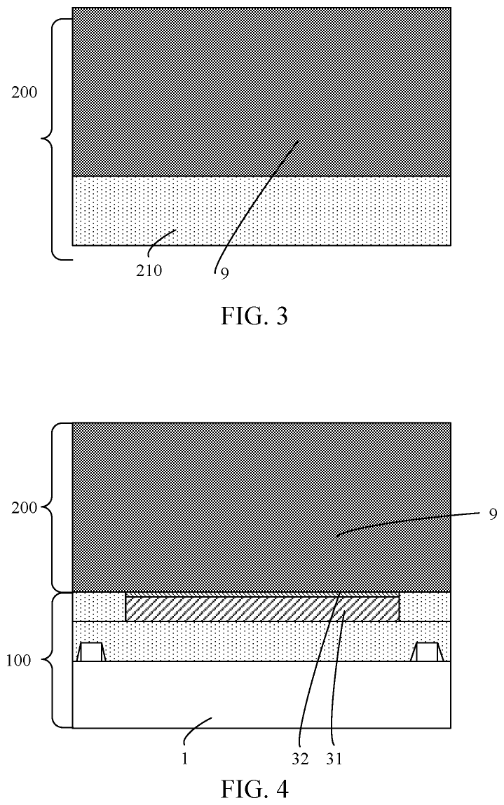

In another exemplary embodiment, the first conductive thin film may be made of, for example, copper (Cu), a copper thin film may be deposited after etching a trench on the first insulating layer 2, the copper thin film is planarized to form the first conductive layer 31 disposed in the trench, then a connection layer thin film is deposited, the connection layer thin film is patterned to form the connection layer 32, and then a third insulating layer 3 is formed. The first conductive layer 31 and the connection layer 32 constitute the bit line layer 30′, as shown in FIG. 2C. The orthographic projection of the connection layer 32 on the substrate 1 may overlap with the orthographic projection of the first conductive layer 31 on the substrate 1.
2) Providing a second wafer 200, wherein the second wafer 200 may include a base substrate 210 and a semiconductor layer 9 disposed on the base substrate 210, as shown in FIG. 3, and FIG. 3 is a cross-sectional view of the second wafer 200 in a direction perpendicular to the base substrate 210.

In an embodiment, the semiconductor layer 9, for example, may include at least one simple-substance semiconductor material (e.g., Silicon (Si), Germanium (Ge)), at least one III-V compound semiconductor material (e.g., Gallium Nitride (GaN), Gallium Arsenide (GaAs), Indium Phosphide (InP)), at least one II-VI compound semiconductor material, at least one organic semiconductor material, or another semiconductor material known in the art.

In an exemplary embodiment, the semiconductor layer 9 may be formed by epitaxial growth on the base substrate 210. In addition, the semiconductor layer 9 has been doped according to doping requirements of the source region, the channel region, and the drain region, and a doping concentration of the channel region may be different from doping concentrations of the source region and the drain region. In an exemplary embodiment, doping may be achieved during the epitaxial growth.
3) Inverting the second wafer 200, then bonding the second wafer to the first wafer 100, and removing the base substrate 210 to expose the semiconductor layer 9, as shown in FIG. 4, and FIG. 4 is a cross-sectional view along the direction perpendicular to the substrate 1 after the bonding. The semiconductor layer 9 is in contact with the connection layer 32. A metal silicide may be formed on a contact surface between the connection layer 32 and the semiconductor layer 9, thereby reducing a contact resistance between the bit line layer 30′ and the semiconductor layer 9.

In an exemplary embodiment, bonding between the second wafer 200 and the first wafer 100 may be Hybrid bonding, followed by an alloy process and Rapid Thermal Annealing (RTA).

In an exemplary embodiment, the base substrate 210 may be removed by process(es) such as grind, Chemical Mechanical Polishing (CMP), wet etch, and combinations of the above.
4) Forming a word line isolation trench T1;

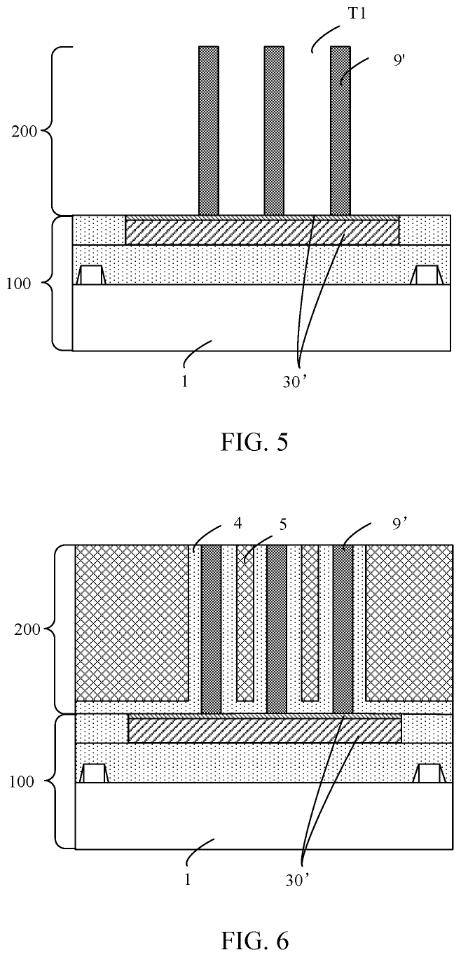

The forming the word line isolation trench T1 may include: etching the semiconductor layer 9 to form a plurality of word line isolation trenches T1 extending in the first direction X. Bottom of a word line isolation trench T1 exposes the bit line layer 30′, i.e., the connection layer 32, as shown in FIG. 5, and FIG. 5 is a cross-sectional view along the AA′ direction after the word line isolation trench T1 is formed. The word line isolation trenches T1 may be distributed at intervals along the second direction Y. At this time, the semiconductor layer 9 is cut into a plurality of independent planar semiconductor portions 9′. The semiconductor portions 9′ are connected to the bit line layer 30′.
5) Forming a third insulating layer 4 and a fourth insulating layer 5;

The forming the third insulating layer 4 and the fourth insulating layer 5 may include: sequentially depositing a third insulating thin film on the substrate 1 on which the aforementioned structures are formed to form a third insulating layer 4; and depositing a fourth insulating thin film to form a fourth insulating layer 5, and planarizing the third and fourth insulating layers so that surfaces of the third insulating layer 4 and the fourth insulating layer 5 away from the substrate 1 are flush with a surface of the semiconductor layer 9 away from the substrate 1, as shown in FIG. 6, FIG. 6 is a schematic cross-sectional view along the AA′ direction after the third insulating layer 4 and the fourth insulating layer 5 are formed.

In an exemplary embodiment, the third insulating film and the fourth insulating film may be deposited by an Atomic Layer Deposition (ALD) method.

In an exemplary embodiment, the third insulating thin film and the fourth insulating thin film may be low-K dielectric layers, i.e. dielectric layers having a dielectric constant K<3.9. For example, their material(s) may be any one or more of silicon nitride (SiNx), silicon oxide (SiOx), silicon oxynitride (SiON), and silicon carbide (SiC).

In an exemplary embodiment, the third insulating film may be made of silicon oxide.

In an exemplary embodiment, the fourth insulating thin film may be made of silicon nitride.
6) Forming a bit line 30;

The forming the bit line 30 may include:
forming a plurality of bit line isolation trenches T2 extending in the second direction Y, wherein the bit line isolation trenches T2 expose the first insulating layer 2, the bit line isolation trenches T2 divide the bit line layer 30′ into a plurality of bit lines 30, and divide the semiconductor portion 9′ into a plurality of semiconductor pillars 10.

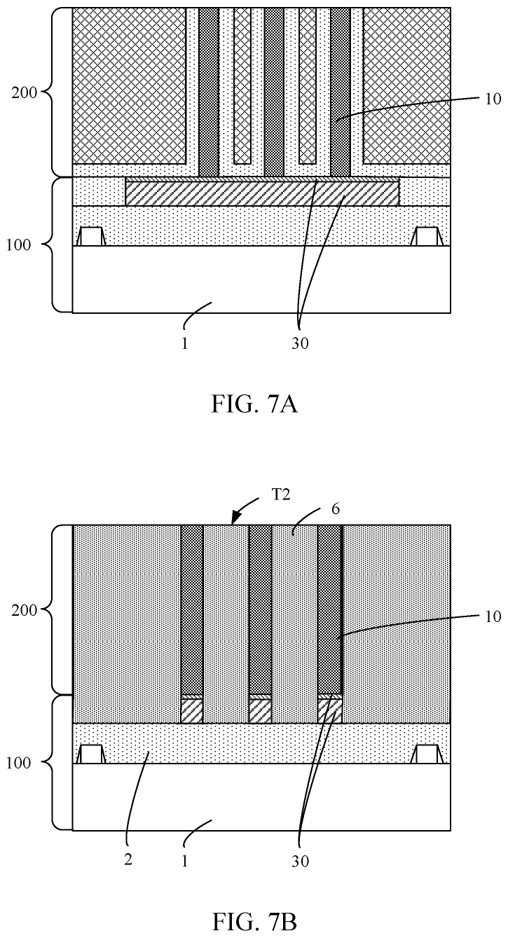

A fifth insulating thin film is deposited on the substrate 1 on which the aforementioned structures are formed to form a fifth insulating layer 6 filling the bit line isolation trenches T2, as shown in FIGS. 7A and 7B, FIG. 7A is a cross-sectional view along the AA′ direction after the bit lines 30 are formed, and FIG. 7B is a cross-sectional view along the CC′ direction after the bit lines 30 are formed. The bit line isolation trenches T2 may be distributed at intervals along the first direction X.

In some embodiments, a quantity of the bit lines 30 may be related to a quantity of columns of the semiconductor pillars 10, and one bit line 30 may correspond to one column of semiconductor pillars 10.

In some embodiments, the bit lines 30 may be strip electrodes.

In some embodiments, an orthographic projection of a bit line 30 may be a rectangle on a plane parallel to the substrate 1.

In some embodiments, each of the bit lines 30 may be connected to one column of semiconductor pillars 10 distributed along the second direction Y.

In an exemplary embodiment, the depositing the fifth insulating thin film on the substrate 1 on which the aforementioned structures are formed may include: depositing a sixth insulating thin film by ALD on the substrate 1 on which the aforementioned structures are formed to form a first insulating sublayer, and then depositing the fifth insulating thin film by applying a Spin Oxide Dielectric (SOD) to form a second insulating sublayer, and the first insulating sublayer and the second insulating sublayer constitute the fifth insulating layer 6.

In an exemplary embodiment, the fifth insulating film may be a low-K dielectric layer, such as any one or more combinations of silicon nitride (SiNx), silicon oxide (SiOx), silicon oxide nitride (SiON), silicon carbide (SiC), and black diamond.
7) Exposing the channel region 11 and the first region 12;

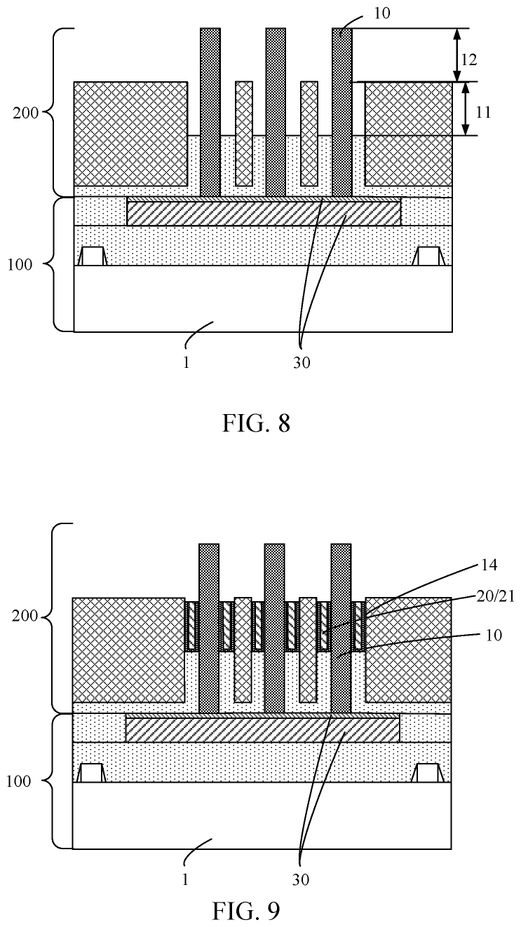

The exposing the channel region 11 and the first region 12 may include etching the fourth insulating layer 5 and the third insulating layer 4, to expose the channel region 11 and the first region 12, as shown in FIG. 8, and FIG. 8 is a cross-sectional view along the AA′ direction after the channel region 11 and the first region 12 are exposed. The exposing the channel region 11 includes exposing sidewalls of the channel region 11, and the exposing the first region 12 includes exposing sidewalls and a top surface (surface away from the substrate 1) of the first region 11.
8) Forming a gate insulating layer 14 and a gate electrode 21;
the forming the gate insulating layer 14 and the gate electrode 21 may include: sequentially depositing a gate insulating thin film and a gate electrode thin film on the substrate 1 on which the aforementioned structures are formed;
etching the gate insulating thin film and the gate electrode thin film, to expose the first region 12, so as to form the gate insulating layer 14 and the gate electrode 21, as shown in FIG. 9, wherein FIG. 9 is a cross-sectional view along the AA′ direction after the gate insulating layer 14 and the gate electrode 21 are formed. Gate electrodes 21 of transistors in a same column are connected to form the word line 20. The gate insulating layer 14 is provided between a gate electrode 21 and a semiconductor pillar 10 to isolate the semiconductor pillar 10 and the gate electrode 21. The exposing the first region 12 may include exposing sidewalls and a top surface of the first region 12.

In an exemplary embodiment, the gate insulating thin film may be made of a High-K dielectric material including, but not limited to, at least one of the following: a single-layer structure or a multilayer structure of at least one of silicon oxide, aluminum oxide, silicon nitride, hafnium oxide, and silicon oxynitride.

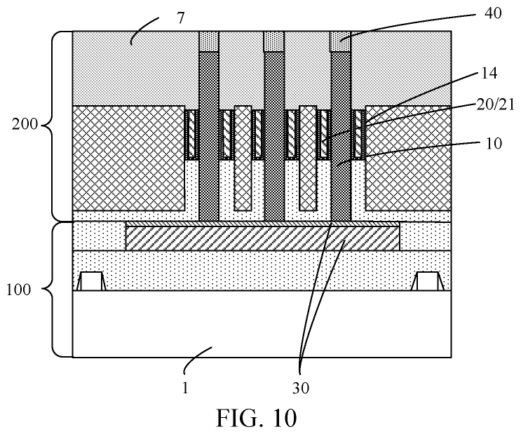

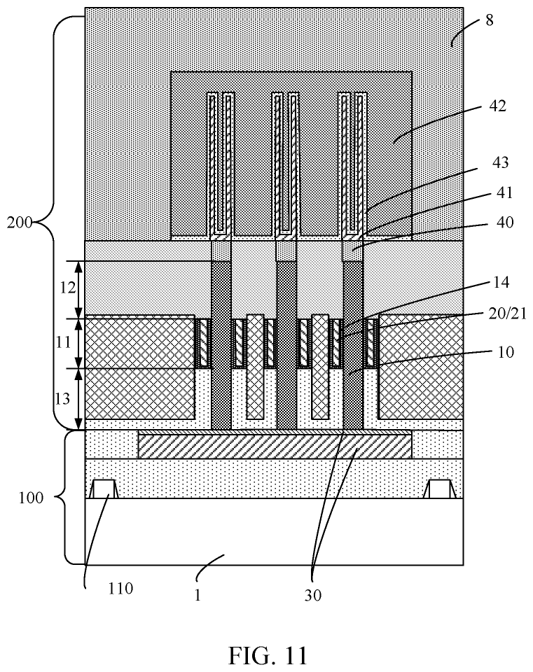

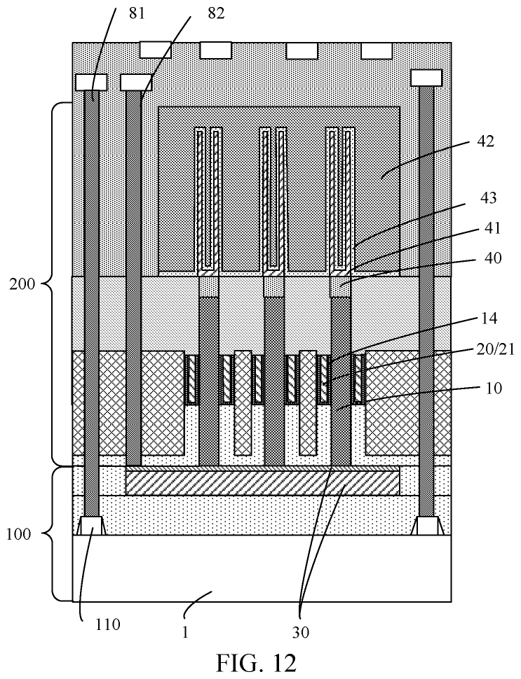

In an exemplary embodiment, the gate electrode thin film may be formed of or include a conductive material, and the conductive material may be, for example, one of a doped semiconductor material, a conductive metal nitride, a metal material, and a metal-semiconductor compound.
9) Forming a node contact layer 40;
the forming the node contact layer 40 may include:
depositing a sixth insulating thin film on the substrate 1 on which the above structures are formed to form a sixth insulating layer 7; wherein a first distance between a surface of the sixth insulating layer 7 away from the substrate 1 and the substrate 1 is larger than a second distance between a surface of the semiconductor pillar 10 away from the substrate 1 and the substrate 1, and for example, the difference between the first distance and the second distance may be 50 Angstroms to 1000 Angstroms;
forming a plurality of vias exposing the top ends of the semiconductor pillars 10 on the sixth insulating layer 7, and depositing a second conductive thin film in the vias and planarizing the second conductive thin film to form a node contact layer 40, as shown in FIG. 10, wherein FIG. 10 is a cross-sectional view along the AA′ direction after the node contact layer 40 is formed. The node contact layer 40 is in contact with a surface of the first region 12 away from the substrate 1.

In an exemplary embodiment, an orthographic projection of the node contact layer 40 on the substrate 1 overlaps with the orthographic projection of the first region 12 on the substrate 1.

In an exemplary embodiment, the second conductive thin film may be a polysilicon thin film, such as highly phosphorus doped polysilicon. The node contact layer 40 may reduce a contact resistance between the subsequently formed first capacitive electrode 41 and the first region 12.
10) Form a capacitor;
the forming the capacitance may include:
depositing a first conductive material on the substrate 1 on which the aforementioned structures are formed, patterning the first conductive material to form a first capacitive electrode 41 disposed on a surface of the node contact layer 40;
depositing a dielectric material on the substrate 1 on which the aforementioned structures are formed, and patterning the dielectric material to form a dielectric layer 43;
depositing a second conductive material on the substrate 1 on which the aforementioned structures are formed, and patterning the second conductive material to form a second capacitive electrode 42;
depositing a seventh insulating thin film on the substrate 1 on which the aforementioned structures are formed to form a seventh insulating layer 8, as shown in FIG. 11, wherein FIG. 11 is a schematic cross-sectional view along the AA′ direction after the capacitor is formed.

In an exemplary embodiment, the first conductor material or the second conductor material may include at least one of metallic materials (e.g., titanium, tantalum, tungsten, copper, and aluminum), conductive metal nitrides (e.g., titanium nitride and tantalum nitride), and doped semiconductor materials (e.g., doped silicon and doped germanium), is formed of or includes, for example, at least one of metallic materials (e.g., titanium, tantalum, tungsten, copper, and aluminum), conductive metal nitrides (e.g., titanium nitride and tantalum nitride), and doped semiconductor materials (e.g., doped silicon and doped germanium).

In an exemplary embodiment, the dielectric material includes, for example, one or a combination of zirconia (ZrO2)/aluminum oxide (Al2O3)/zirconia (ZrO2) stacked structure, hafnium oxide, strontium titanate, hafnium silicon oxide, lanthanum oxide, zirconia, zirconia silicon oxide, tantalum oxide, titanium oxide, barium titanium oxide, strontium titanium oxide, lithium oxide, aluminum oxide, lead scandium tantalum oxide, lead zinc niobate.

In an exemplary embodiment, the dielectric layers 43 of capacitors to which transistors in the storage array are connected, may be connected to form an integrated structure.

In an exemplary embodiment, the second capacitive electrodes 42 of capacitors to which transistors in the storage array are connected, may be connected to form an integrated structure. The integrated structure may be, for example, an entire surface electrode.

In an exemplary embodiment, the first capacitive electrode 41 may have a U-shape along a cross section perpendicular to the substrate 1, the first capacitive electrode 41 may have a cylindrical shape having an open end, and the second capacitive electrode 42 may fill internal space of the cylindrical shape.
11) Implementing interconnection between the logic circuit and the storage array;

The implementing the interconnection between the logic circuit and the storage array may include forming a first through via penetrating the seventh insulating layer 8, the sixth insulating layer 7, the fourth insulating layer 5, the third insulating layer 4, the second insulating layer 3, and the first insulating layer 2, and forming a second through via penetrating the seventh insulating layer 8, the sixth insulating layer 7, the fourth insulating layer 5, and the third insulating layer 4, with the first through via exposing the logic circuit 110, and the second through via exposing the bit line 30; depositing a third conductive thin film in the first via to form a first connection electrode 81, and depositing the third conductive thin film in the second via to form a second connection electrode 82, as shown in FIG. 12, wherein FIG. 12 is a cross-sectional view along the AA′ direction after the interconnection is implemented. The first connection electrode 81 and the second connection electrode 82 may be connected to an external circuit, and subsequently, a signal may be loaded to the logic circuit via the first connection electrode 81, a signal may be loaded to the bit line 30 via the second connection electrode 82, and the like. A ReDistribution Layer (RDL) may also be provided, which is packaged after rewiring. FIG. 12 illustrates some pads of the rewiring layer, which is merely an example, and the embodiments of the present disclosure are not limited thereto.

In an exemplary embodiment, the first through via and the first connection electrode, the second through via and the second connection electrode may be formed by a Through Silicon Via (TSV) technique, for example, after the first through via is formed, a seed layer including tantalum (Ta) or tantalum nitride (TaN) and copper (Cu) is deposited in the first through via, a copper (Cu) thin film is formed on the seed layer by Electropolishing (ECP), and the copper thin film is planarized, for example by Chemical Mechanical Polishing (CMP), to form the first connection electrode. Or, after the TSV through vias are formed, Ti and TiN thin films are grown, and then metal tungsten is filled, and finally planarized by CMP. The case for the second connection electrode is similar and will not be described in detail.

In the above embodiment, the structure of 1T1C is described as an example, but the embodiments of the present disclosure are not limited thereto, and the transistor may be combined with other devices, for example, the transistor and another transistor may constitute a 2T0C storage structure, and the like.

In the above embodiment, two wafers are used, a transistor is manufactured on one wafer, a bit line layer is manufactured on the other wafer, and subsequently the bit line layer is directly etched to form a bit line. Compared with the scheme of etching a trench at bottom of a semiconductor pillar and filling a conductive material therein to form a bit line in the related art, the scheme of the embodiment of the present disclosure has a simple process, can avoid formation of a cavity in the bit line, and the shape of the bit line is more stable, and the contact resistance between the bit line and the semiconductor pillar is more stable. In addition, sizes and shapes of different bit lines of a same storage array are easier to control, and the sizes and shapes of different bit lines can be made uniform, so that a resistance of the bit line can be stabilized.

The structure shown in this embodiment and the manufacturing process thereof are merely exemplary illustrations. In actual implementation, corresponding structures can be altered and patterning processes can be added or reduced according to actual needs.

An embodiment of the present disclosure further provides an electronic equipment including the semiconductor device of the aforementioned embodiment. The electronic equipment may be a storage apparatus, a smartphone, a computer, a tablet computer, an artificial intelligence device, a wearable device, a Graphics Processing Unit (GPU), a near memory computing or a mobile power supply, or the like. The storage apparatus may include a memory in a computer or the like, which is not limited here.

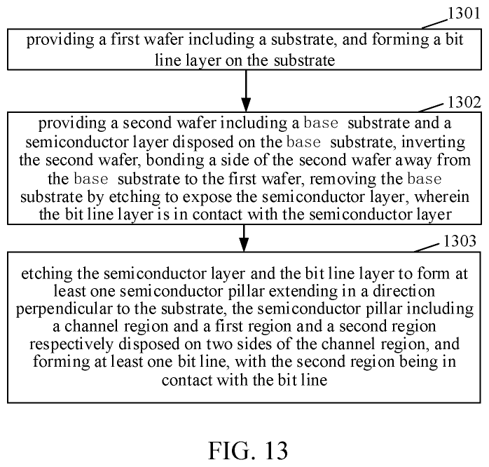

FIG. 13 is a flowchart of a method for manufacturing a semiconductor device according to an embodiment of the present disclosure. As shown in FIG. 13, an embodiment of the present disclosure provides a method for manufacturing a semiconductor device, wherein the semiconductor device includes at least one transistor including a semiconductor pillar, and the method includes:
Act 1301: providing a first wafer including a substrate, and forming a bit line layer on the substrate;
Act 1302: providing a second wafer including a base substrate and a semiconductor layer disposed on the base substrate, inverting the second wafer, bonding a side of the second wafer away from the base substrate to the first wafer, removing the base substrate by etching to expose the semiconductor layer, wherein the bit line layer is in contact with the semiconductor layer;
Act 1303: etching the semiconductor layer and the bit line layer to form at least one semiconductor pillar extending in a direction perpendicular to the substrate, the semiconductor pillar including a channel region and a first region and a second region respectively disposed on two sides of the channel region, with the second region being disposed on a side of the channel region facing the substrate, and forming at least one bit line, with the second region being in contact with the bit line.

In the embodiment, a structure, a material, a related parameter, and a detailed manufacturing process of each film layer have been described in detail in the foregoing embodiments, and will not be repeated here.

In the method for manufacturing the semiconductor device provided by the embodiment of the present disclosure, the bit line and the transistor are manufactured on different wafers respectively, the process is simple, the formation of cavities in the bit line can be avoided, the shape of the bit line is more stable, and the contact resistance between the bit line and the semiconductor pillar is more stable. In addition, during manufacturing of the storage array, sizes and shapes of different bit lines of a same storage array are easier to control, and the sizes and shapes of different bit lines can be made uniform, so that a resistance of the bit line can be stabilized. Moreover, the manufacturing method can be achieved by using existing equipment and is easy to implement.

In an exemplary embodiment, the etching the semiconductor layer and the bit line layer may include:
forming a plurality of word line isolation trenches extending in a first direction, the word line isolation trenches penetrating the semiconductor layer and exposing the bit line layer, the word line isolation trenches dividing the semiconductor layer into a plurality of semiconductor portions;
forming a plurality of bit line isolation trenches extending in a second direction and penetrating the bit line layer, the bit line isolation trenches dividing the bit line layer into a plurality of bit lines, the second direction intersecting the first direction.

In an exemplary embodiment, the providing the second wafer may include epitaxially growing on the base substrate and doping the base substrate to form a semiconductor layer.

In an exemplary embodiment, the forming the bit line layer on the substrate may include:
depositing a first insulating thin film on the substrate to form a first insulating layer;
sequentially depositing a first conductive thin film and a connection layer thin film on the first insulating layer to form a bit line layer by patterning;

Or, depositing a first insulating thin film on the substrate to form a first insulating layer;
depositing a first conductive thin film after etching a trench on the first insulating layer, and planarizing the first conductive thin film to form a first conductive layer disposed in the trench;
depositing a connection layer thin film and patterning the connection layer thin film to form a connection layer, wherein the first conductive layer and the connection layer constitute the bit line layer, and an orthographic projection of the connection layer on the substrate overlaps with an orthographic projection of the first conductive layer on the substrate.

In an exemplary embodiment, before forming the bit line layer on the substrate, the method further includes forming a logic circuit on the substrate.

Although implementations disclosed in the present disclosure are as the above, the described contents are only implementations used for facilitating understanding the present invention, and are not intended to limit the present disclosure. Any person skilled in the art to which the present disclosure pertains may make any modification and variation in the form and details of implementations without facing away from the spirit and the scope disclosed in the present disclosure. Nevertheless, the scope of patent protection of the present disclosure shall still be subject to the scope defined by the appended claims.

1. A semiconductor device comprising: a first wafer and a second wafer disposed on the first wafer, wherein the first wafer comprises a substrate and a bit line disposed on the substrate;
the second wafer comprises at least one transistor comprising a semiconductor pillar extending in a direction perpendicular to the substrate, the semiconductor pillar comprises a channel region and a first region and a second region respectively disposed on two sides of the channel region, the second region is disposed on a side of the channel region facing the substrate, and the bit line is in contact with the second region.

2. The semiconductor device of claim 1, wherein a contact surface of the bit line with the second region is parallel to the substrate.

3. The semiconductor device of claim 1, wherein a surface of the bit line close to the substrate is parallel to the substrate.

4. The semiconductor device of claim 1, wherein an orthographic projection of the bit line comprises a rectangle on a plane parallel to the substrate.

5. The semiconductor device of claim 1, wherein the second wafer comprises a plurality of transistors distributed in an array along a first direction and a second direction respectively, the first wafer comprises a plurality of bit lines extending along the second direction, second regions of transistors of a same column distributed along the second direction are connected to a same bit line, and the first direction and the second direction intersect.

6. The semiconductor device of claim 5, wherein a transistor further comprises: a gate electrode surrounding a sidewall of the channel region, and gate electrodes of a same row of transistors distributed along the first direction are connected to form a word line.

7. The semiconductor device of any one of claims 1 to 6, further comprising a logic circuit disposed on a side of the bit line away from the second wafer.

8. The semiconductor device of claim 7, wherein an orthographic projection of the logic circuit on the substrate overlaps with an orthographic projection of the transistor on the substrate.

9. An electronic equipment, comprising the semiconductor device of any one of claims 1 to 8.

10. The electronic equipment of claim 9, wherein the semiconductor device further comprises a capacitor disposed on a side of the transistor away from the first wafer, the capacitor comprises a first capacitive electrode, a second capacitive electrode, and a dielectric layer disposed between the first capacitive electrode and the second capacitive electrode, the first capacitive electrode is connected to the first region through a node contact layer.

11. A method for manufacturing a semiconductor device comprising at least one transistor comprising a semiconductor pillar, the method comprising:
providing a first wafer comprising a substrate, and forming a bit line layer on the substrate;
providing a second wafer comprising a base substrate and a semiconductor layer disposed on the base substrate, inverting the second wafer, bonding a side of the second wafer away from the base substrate to the first wafer, removing the base substrate by etching to expose the semiconductor layer, wherein the bit line layer is in contact with the semiconductor layer; and
etching the semiconductor layer and the bit line layer to form at least one semiconductor pillar extending in a direction perpendicular to the substrate, the semiconductor pillar comprising a channel region and a first region and a second region respectively disposed on two sides of the channel region, with the second region being disposed on a side of the channel region facing the substrate, and forming at least one bit line, with the second region being in contact with the bit line.

12. The method for manufacturing the semiconductor device of claim 11, wherein the etching of the semiconductor layer and the bit line layer comprises:
forming a plurality of word line isolation trenches extending in a first direction, the word line isolation trenches penetrating the semiconductor layer and exposing the bit line layer, and the word line isolation trenches dividing the semiconductor layer into a plurality of semiconductor portions; and
forming a plurality of bit line isolation trenches extending in a second direction and penetrating the bit line layer, the bit line isolation trenches dividing the bit line layer into a plurality of bit lines, the second direction intersecting the first direction.

13. The method for manufacturing the semiconductor device of claim 11, wherein the providing the second wafer comprises epitaxially growing on the base substrate and doping the base substrate to form the semiconductor layer.

14. The method for manufacturing the semiconductor device of claim 11, wherein the forming the bit line layer on the substrate comprises:
depositing a first insulating thin film on the substrate to form a first insulating layer;
sequentially depositing a first conductive thin film and a connection layer thin film on the first insulating layer to form the bit line layer by patterning; or depositing a first insulating thin film on the substrate to form a first insulating layer;
depositing a first conductive thin film after etching a trench on the first insulating layer, and planarizing the first conductive thin film to form a first conductive layer disposed in the trench; and
depositing a connection layer thin film and patterning the connection layer thin film to form a connection layer, wherein the first conductive layer and the connection layer constitute the bit line layer, and an orthographic projection of the connection layer on the substrate overlaps with an orthographic projection of the first conductive layer on the substrate.

15. The method for manufacturing the semiconductor device of any one of claims 11 to 14, wherein, before forming the bit line layer on the substrate, the method further comprises forming a logic circuit on the substrate.
